(19) United States
(12) Patent Application Publication
(10) Pub. No.: US 2008/0072957 A1
(43) Pub. Date: Mar. 27, 2008

(54) SOLAR CELL UNITS AND MODULES COMPRISING THE SAME

(75) Inventors: Yu-Yang Chang, Tainan (TW); Ming-Hung Lin, Taipei City (TW); Bing-Nan Lin, Taichung City (TW); Cheng-Chung Lee, Taitung County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, Hsinchu (TW)

(21) Appl. No.: 11/616,246

(22) Filed: Dec. 26, 2006

(30) Foreign Application Priority Data
Sep. 7, 2006 (TW) 95133029

(51) Int. Cl. H01L 31/00

(52) U.S. Cl. 136/256

(57) ABSTRACT

A solar cell unit. The solar cell unit includes a first tubulate structure, an electron transfer layer coated thereon, a second tubulate structure, a metal layer coated thereon, a space formed between the first and second tubulate structures, a dye layer coated on the electron transfer layer, and an electrolyte filled in the space, wherein the diameters of the first and second tubulate structures are different and the electron transfer layer is opposite to the metal layer. The invention also provides a module including a plurality of the solar cell units.

### BACKGROUND OF THE INVENTION

1. Field of the Invention

The invention relates to a solar cell unit, and in particular to tubulate solar cell units and a module comprising the same.

2. Description of the Related Art

Currently, development of solar cell technology is focused on low cost and high photoconversion efficiency such as with thin film solar cell or multi-junction solar cell.

Among thin film solar cells, dye-sensitized solar cells (DSSC, Graetzel Cell) are popular due to low cost and simple fabrication. Currently, the highest photoconversion efficiency of dye-sensitized solar cells is 11%. Switzerland EPFL group discloses a small-area (less than 1 cm²) dye-sensitized solar cell with 10.8% photoconversion efficiency. Netherlands ECN institute discloses a dye-sensitized solar cell with 8.23% photoconversion efficiency. However, photoconversion efficiency of large-area (exceeding 1 cm²) dye-sensitized solar cell is still less than 7%. Additionally, Australia STA produced a first 10 cm²-area dye-sensitized solar cell system with 5% photoconversion efficiency in 2003. Chinese Academy of Science produced a dye-sensitized solar cell system (500 W) with 5% photoconversion efficiency in 2004.

Referring to FIG. 1A, a conventional dye-sensitized solar cell is disclosed. A dye-sensitized solar cell 10 is composed of an upper conductive glass substrate 12 and a lower conductive glass substrate 14. A solution containing titanium dioxide precursor is coated on the upper conductive glass substrate 12. After heating, a spongy porous titanium dioxide layer 16 with a larger surface area is formed. Next, a dye solution containing ruthenium, anthocyanidins, or chlorophyll is coated on the titanium dioxide layer 16 to form a dye layer 18 as a light absorber. An electrolyte 20 containing iodine ions is then filled in the dye layer 18.

A metal catalyst layer 22, such as platinum (Pt), is coated on the lower conductive glass substrate 14 to form a corresponding electrode. Finally, the upper conductive glass substrate 12 and the lower conductive glass substrate 14 are assembled to form a solar cell device 10. Electrons are driven by exposure of the titanium dioxide layer 16. In FIG. 1B, the inner electron transfer mechanism is illustrated. Electrons are effectively transferred only by the dye molecules 18 near to the titanium dioxide layer 16. However, the adsorption area of the dye layer 18 is small due to the dense titanium dioxide layer 16, reducing light energy absorption, resulting in low photoconversion efficiency (less than 1%).

Recently, porous nano-structured electrode technology has effectively solved the existing problems, providing more catalyst surface area than the smooth electrode by about a thousand times, improving photoconversion efficiency. Michael Graetzel indicated that photoconversion efficiency of dye-sensitized solar cell can thus be improved from less than 1% to 11%. Clearly, efficiency of dye-sensitized solar cell depends on titanium dioxide electrode structure. For example, dye absorption amounts are determined by inner surface area of titanium dioxide, diffusion of redox pairs is affected by distribution of porous size, optical properties are affected by distribution of particle size, and particle connection is determined by electron flow. Further, dye absorption amounts and electron-hole pair numbers converted from photons are proportionate. Thus, increased inner surface area of titanium dioxide per unit area can effectively improve photoconversion efficiency of dye-sensitized solar cell.

To increase inner surface area of titanium dioxide per unit area, alteration of solar cell structure can also be considered in addition to materials and fabrication. For a planar solar cell unit, a cathode layer and an anode layer are coated on inner sides of upper and lower substrates, respectively. Then, these solar cell units are mosaicked to form a large-area module, obtaining sufficient power output. If photoreaction area is enlarged, that is, inner surface area of titanium dioxide layer is increased in the same planar area, more power outputs are acquired.

### BRIEF SUMMARY OF THE INVENTION

The invention provides a solar cell unit comprising a first tubulate structure, an electron transfer layer coated thereon, a second tubulate structure, a metal layer coated thereon, a space formed between the first and second tubulate structures, a dye layer coated on the electron transfer layer, and an electrolyte filled in the space, wherein the diameters of the first and second tubulate structures are different and the electron transfer layer is opposite to the metal layer.

The invention also provides a solar cell module comprising a plurality of the disclosed solar cell units.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1A is a cross section of a conventional dye-sensitized solar cell unit.

FIG. 1B shows mechanism of a conventional dye-sensitized solar cell unit.

FIG. 2 is a top view of a dye-sensitized solar cell unit of the invention.

FIG. 3 is a cross section of FIG. 2 along 3-3′ line.

FIGS. 4˜6 show a dye-sensitized solar cell module design of the invention.

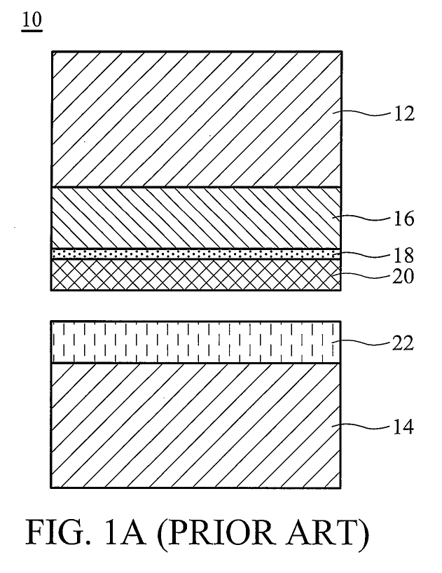

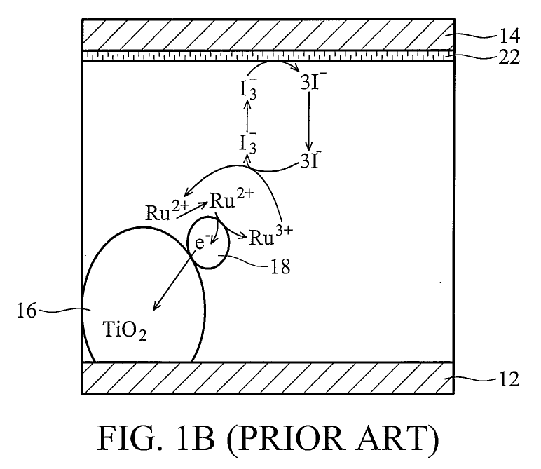

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a solar cell unit comprising a first tubulate structure, an electron transfer layer coated thereon, a second tubulate structure, a metal layer coated thereon, a space formed between the first and second tubulate structures, a dye layer coated on the electron transfer layer, and an electrolyte filled in the space, wherein the diameters of the first and second tubulate structures are different and the electron transfer layer is opposite to the metal layer.

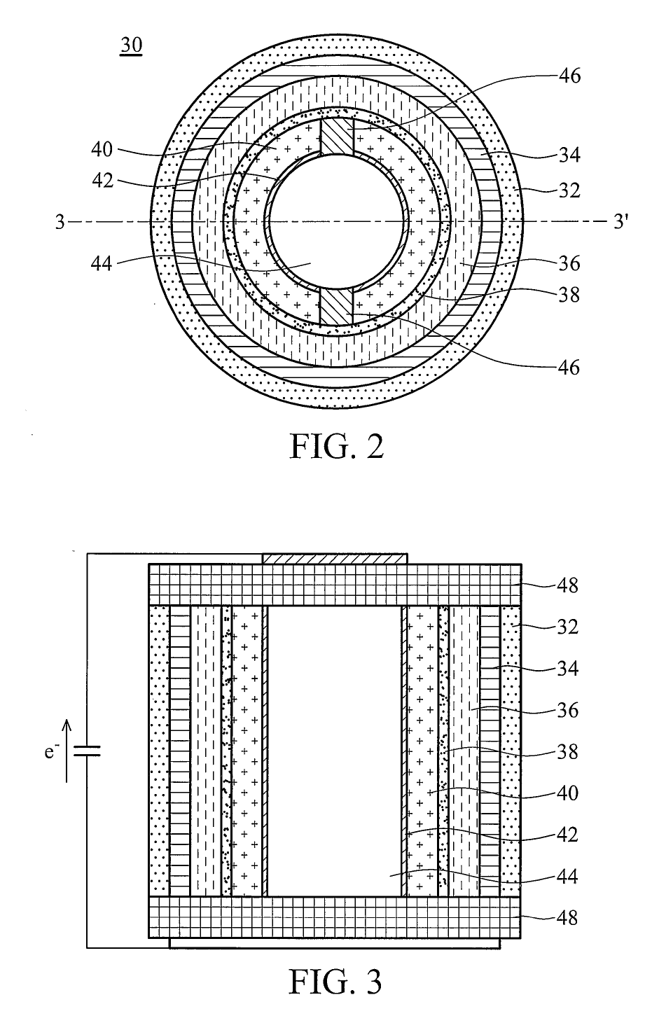

Referring to FIGS. 2 and 3, a solar cell unit structure of the invention is disclosed. FIG. 2 is a top view of a solar cell unit and FIG. 3 is a cross section thereof along 3-3′ line.

In FIG. 2, a solar cell unit 30 comprises a first tubulate structure 32, a conductive layer 34, an electron transfer layer 36, a dye layer 38, an electrolyte 40, a metal layer 42, and a second tubulate structure 44 from outside to inside. The conductive layer 34 is formed on the first tubulate structure 32. The electron transfer layer 36 is coated on the conductive layer 34. The dye layer 38 is coated on the electron transfer layer 36. The metal layer 42 is coated on the second tubulate structure 44, opposite to the electron transfer layer 36. The electrolyte 40 is filled in the space formed between the dye layer 38 and the metal layer 42. Rib structures 46 are formed on the second tubulate structure 44 to regulate the space. A sealing material 48 is used to seal the first tubulate structure 32 and the second tubulate structure 44, as shown in FIG. 3. Specifically, the first tubulate structure 32 and the second tubulate structure 44 have different diameters, but the same shape.

The first tubulate structure 32 and the second tubulate structure 44 may comprise glass, metal, alloy, or polymer. They have different diameters, wherein one with a smaller diameter is hollow or solid. The first and second tubulate structures may be straight, bent, semicircular, or spiral, but are not limited thereto.

The conductive layer 34 may comprise indium tin oxide (ITO) or aluminum zinc oxide (AZO). The electron transfer layer 36 may be a titanium dioxide (TiO₂) layer. The dye layer 38 may comprise ruthenium, anthocyanidins, or chlorophyll.

The metal layer 42 may comprise palladium (Pd) or platinum (Pt). The electrolyte 40 may comprise iodine ion. The space formed between the first and second tubulate structures is equidistant, about less than 50 μm.

Photoreaction area is increased by the disclosed tubulate solar cell unit. Compared to a conventional planar solar cell unit, a straight-tube solar cell unit provides about three times the surface area for electron transfer layer coating, an effectively increased photoreaction area. Other than the requirement for tubulate structures having the same shapes and different diameters, the shape thereof is not limited, being equally applicable with straight, bent, semicircular, or spiral structures, being thus considerably more versatile than the planar structure.

The invention also provides a solar cell module comprising a plurality of the disclosed solar cell units.

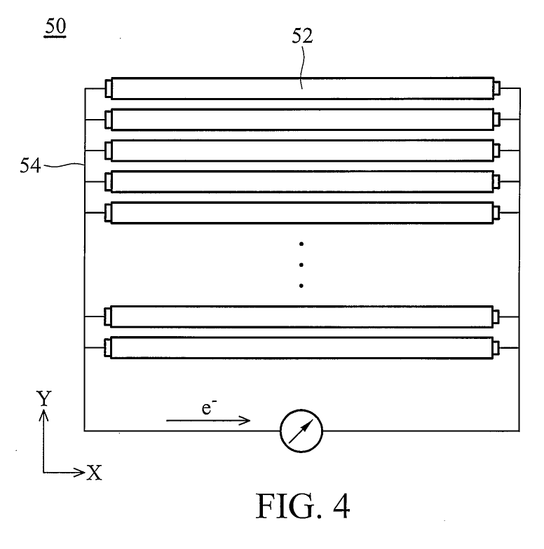

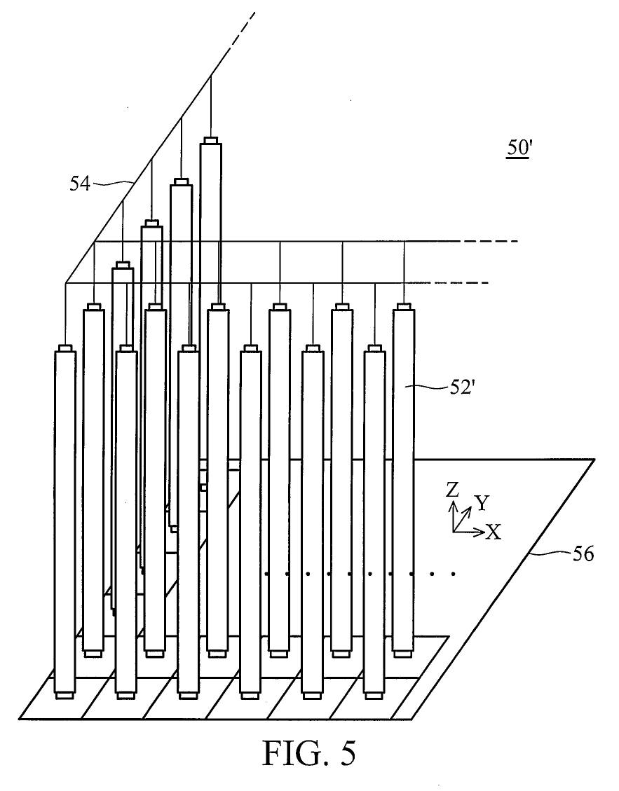

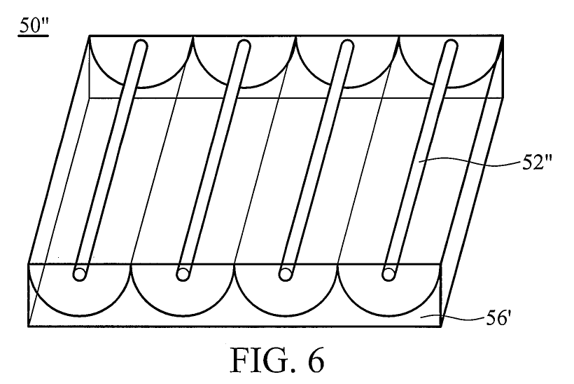

FIGS. 4˜6 show a solar cell module of the invention.

Referring to FIG. 4, a solar cell module 50 comprises a plurality of solar cell units 52, each horizontally arranged and connected by a conductive line 54.

As shown in FIG. 5, a solar cell module 50′ comprises a plurality of solar cell units 52′, each vertically arranged and connected by a conductive line 54. A reflection apparatus 56, such as a reflective plate, is disposed at the bottom of the solar cell units 52′ for improved photoconversion efficiency.

Referring to FIG. 6, a solar cell module 50″ comprises a plurality of tube-type solar cell units 52″. A reflection apparatus 56′, such as a reflective plate, at the bottom of the solar cell units 52″, improves photoconversion efficiency.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell unit, comprising:
a first tubulate structure;
an electron transfer layer coated on the first tubulate structure;
a second tubulate structure;
a metal layer coated on the second tubulate structure, wherein the diameters of the first and second tubulate structures are different and the electron transfer layer is opposite to the metal layer;
a space formed between the first and second tubulate structures;
a dye layer coated on the electron transfer layer; and
an electrolyte filled in the space.

2. The solar cell unit as claimed in claim 1, wherein the first and second tubulate structures comprise glass, metal, alloy, or polymer.

3. The solar cell unit as claimed in claim 1, wherein the tubulate structure with a smaller diameter is hollow or solid.

4. The solar cell unit as claimed in claim 1, wherein the first and second tubulate structures are straight, bent, semicircular, or spiral.

5. The solar cell unit as claimed in claim 1, wherein the electron transfer layer is a titanium dioxide (TiO₂) layer.

6. The solar cell unit as claimed in claim 1, further comprising a conductive layer formed between the electron transfer layer and the first tubulate structure.

7. The solar cell unit as claimed in claim 6, wherein the conductive layer comprises indium tin oxide (ITO) or aluminum zinc oxide (AZO).

8. The solar cell unit as claimed in claim 1, wherein the metal layer comprises palladium (Pd) or platinum (Pt).

9. The solar cell unit as claimed in claim 1, wherein the space is equidistant.

10. The solar cell unit as claimed in claim 1, wherein the dye layer comprises ruthenium, anthocyanidins, or chlorophyll.

11. The solar cell unit as claimed in claim 1, wherein the electrolyte comprises iodine ion.

12. A solar cell module comprising a plurality of solar cell units as claimed in claim 1.

13. The solar cell module as claimed in claim 12, wherein the solar cell units have a horizontal or vertical arrangement.

14. The solar cell module as claimed in claim 12, further comprising a conductive line connected with the solar cell units.

15. The solar cell module as claimed in claim 12, further comprising a reflection apparatus at the bottom of the solar cell units.

16. The solar cell module as claimed in claim 15, wherein the reflection apparatus is a reflective plate.
